(19) United States
(12) Patent Application Publication
(10) Pub. No.: US 2024/0312825 A1
(43) Pub. Date: Sep. 19, 2024

(54) Semiconductor Manufacturing Device, Push-up Unit, and Method of Manufacturing Semiconductor Device

(71) Applicant: Fasford Technology Co., Ltd., Minami-Alps City (JP)

(72) Inventors: Akira Saito, Minami-Alps (JP); Takumi Sassa, Minami-Alps (JP); Yuta Ono, Minami-Alps (JP)

(21) Appl. No.: 18/597,040

(22) Filed: Mar. 6, 2024

(30) Foreign Application Priority Data
Mar. 13, 2023 (JP) 2023-039157

(51) Int. Cl. H01L 21/683; H01L 21/68; H01L 21/78

(52) U.S. Cl. CPC H01L 21/6836; H01L 21/78; H01L 21/681; H01L 2221/68327; H01L 2221/68386

(57) ABSTRACT

A semiconductor manufacturing device includes: a wafer holder for holding a dicing tape to which a die is attached; and a push-up unit having a block unit for pushing up the dicing tape. The block unit includes: an outside block having a first-direction length longer than a second-direction length in a planar view and having a plurality of openings; and an inside block placed inside the openings. The inside blocks are plural and are placed side by side along the first direction.

### CLAIM OF PRIORITY

The present application claims priority from Japanese patent application JP 2023-39157 filed on Mar. 13, 2023, the content of which is hereby incorporated by reference into this application.

### BACKGROUND

The present disclosure relates to a semiconductor manufacturing device and can be applied to, for example, a die bonder having a push-up unit.

As one of the manufacturing steps of a semiconductor device, there is a step of peeling dies, which have been diced from a wafer, from a dicing tape. In this peeling step, for example, dies are pushed up by a push-up unit from a back surface of the dicing tape to peel them one by one from the dicing tape retained at a wafer supply unit and then, picked up by means of an adsorption nozzle such as collet mounted on a pick-up head or bonding head.

For example, the push-up unit peels the dicing tape from the periphery of dies by vertically moving a plurality of blocks (for example, Japanese Unexamined Patent Application Publication No. 2022-114399).

### SUMMARY

The dies may be damaged when they are peeled from the dicing tape by means of the push-up unit.

The subject of this disclosure is to provide a technology capable of reducing a damage of the dies. Other subjects and novel features will become apparent from the description of the present specification and the accompanying drawings.

Among this disclosure, a typical one of summary is briefly described as follows.

That is, a semiconductor manufacturing device includes: a wafer holder for holding a dicing tape to which a die is attached; and a push-up unit having a block unit for pushing up the dicing tape. The block unit includes: an outside block having a first-direction length longer than a second-direction length in a planar view and having a plurality of openings; and an inside block placed inside the openings. The inside blocks are plural and are placed side by side along the first direction.

According to this disclosure, the damage of the dies can be reduced.

### BRIEF DESCRIPTION OF THE DRAWINGS

FIG. 1 is a schematic top view showing a constitution example of a die bonder in the present embodiment.

FIG. 2 is a view for describing a schematic constitution when the die bonder is viewed from the arrow A direction in FIG. 1.

FIG. 3 is a schematic cross-sectional view showing an essential portion of the wafer supply unit shown in FIG. 1.

FIG. 4 is a block diagram showing a schematic constitution of the die bonder control system shown in FIG. 1.

FIG. 5 is a flow chart showing a method of manufacturing a semiconductor device by using the die bonder shown in FIG. 1.

FIG. 6 is a view schematically showing the cross-section of the main portion of the push-up unit shown in FIG. 2.

FIG. 7 is a top view of the push-up unit shown in FIG. 6.

FIG. 8 is a view for describing a push-up sequence in one operation example of the push-up unit shown in FIG. 6.

FIG. 9 is a view for describing the push-up sequence in First Modification Example of the push-up unit shown in FIG. 6.

FIG. 10 is a top view of the block unit of a push-up unit in Second Modification Example.

FIG. 11 is a top view of an inside block in Third Modification Example.

FIG. 12 is a top view of the block unit of a push-up unit in Fourth Modification Example.

FIG. 13 is a view schematically showing the cross-section of the main portion of a push-up unit in Fifth Modification Example.

FIG. 14 is a top view of the block unit shown in FIG. 13.

FIG. 15 is a view for describing the push-up sequence of the push-up unit shown in FIG. 13.

FIG. 16 is a view schematically showing the cross-section of the main portion of a push-up unit in Sixth Modification Example.

FIG. 17 is a top view of the block unit shown in FIG. 16.

FIG. 18 is a view schematically showing the cross-section of the main portion of a push-up unit in Seventh Modification Example.

FIG. 19 is a top view of the block unit shown in FIG. 18.

FIG. 20 is a view schematically showing the cross-section of the main portion of a push-up unit in Eighth Modification Example.

FIG. 21 is a top view of the block unit shown in FIG. 20.

FIG. 22 is a top view of the block unit of a push-up unit in Ninth Modification Example.

FIG. 23 is a top view of the block unit of a push-up unit in Tenth Modification Example.

FIG. 24 is a view schematically showing the cross-section of the main portion of a push-up unit in Eleventh Modification Example.

FIG. 25 is a top view of the block unit shown in FIG. 24.

FIG. 26 is a view schematically showing the cross-section of the main portion of a push-up unit in Twelfth Modification Example.

FIG. 27 is a top view of the block unit shown in FIG. 26.

FIG. 28 is a cross-sectional view of the main portion of a push-up unit in Thirteenth Modification Example.

FIG. 29 is a cross-sectional view of the main portion of a push-up unit in Fourteenth Modification Example.

### DESCRIPTION OF THE PREFERRED EMBODIMENTS

An embodiment and modification examples will be described below with reference to the drawings. It should be noted that in the following description, the same components are indicated by the same reference numerals, and the repeated description thereof may be omitted. It should be noted that to make the description more clearly, the drawings may be schematically represented for the widths, thicknesses, shapes, and the like of the respective portions as compared with the actual form. In addition, also between a plurality of mutual drawings, the dimension relationships between the respective elements, the ratios between the respective elements, and the like do not always coincide with each other.

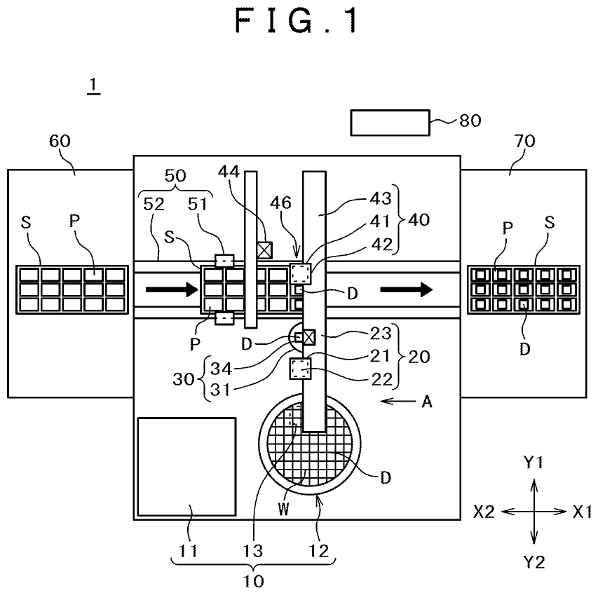

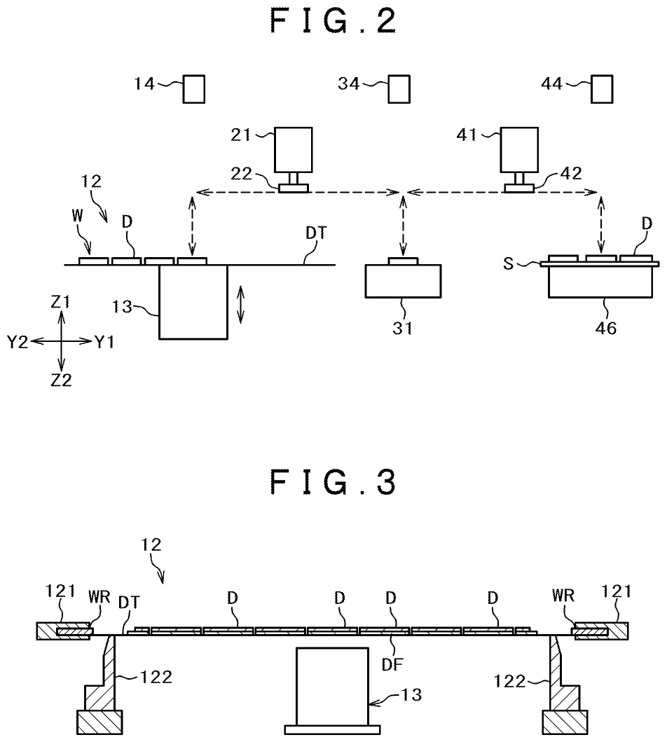

The constitution of a die bonder which is one embodiment of a semiconductor manufacturing device will hereinafter be described referring to FIGS. 1 to 3. FIG. 1 is a schematic top view showing a constitution example of a die bonder in the present embodiment. FIG. 2 is a view for describing a schematic constitution when the die bonder is viewed from the arrow A direction in FIG. 1. FIG. 3 is a schematic cross-sectional view showing an essential portion of the wafer supply unit shown in FIG. 1.

The die bonder 1 roughly has a wafer supply unit 10, a pick-up unit 20, an intermediate stage unit 30, a bonding unit 40, a carrier unit 50, a substrate supply unit 60, a substrate unloading unit 70, and a control unit (controller) 80. A Y2-Y1 direction is a front-back direction of the die bonder 1, a X2-X1 direction is a left-right direction, and a Z1-Z2 direction is a vertical direction. The die bonder 1 has, on the front side thereof, the wafer supply unit 10 and, on the back side, the bonding unit 40.

The wafer supply unit 10 has a wafer cassette lifter 11, a wafer holder 12, a push-up unit 13, and a wafer recognition camera 14.

The wafer cassette lifter 11 vertically moves, to a wafer carrying height, a wafer cassette (not shown) in which a plurality of wafer rings WR are to be housed. A wafer correction chute (not shown) aligns the wafer rings WR supplied from the wafer cassette lifter 11. A wafer extractor (not shown) takes out the wafer rings WR from the wafer cassette to supply them to the wafer holder 12; or takes them out from the wafer holder 12 and house them in the wafer cassette.

The wafer holder 12 has an expand ring 121 for holding the wafer rings WR and a support ring 122 that is supported by the wafer rings WR and horizontally positions a dicing tape DT. The push-up unit 13 is placed inside the support ring 122.

A wafer W is adhered (attached) onto the dicing tape DT and this wafer W is divided into a plurality of dies D. The dicing tape DT is transparent to a visible light. A film-form adhesion material DF which is called “die-attach film (DAF)” is attached between the wafer W and the dicing tape DT. The adhesion material DF cures by heating.

The wafer holder 12 moves in the X1-X2 direction and the Y1-Y2 direction by a drive unit which is not shown and the dies D to be picked up are moved to the position of the push-up unit 13. In addition, the wafer holder 12 rotates the wafer rings WR in an XY plane by the drive unit which is not shown. The push-up unit 13 is vertically moved by the drive unit not shown. The push-up unit 13 peels the dies D from the dicing tape DT. The wafer holder 12 and the push-up unit 13 constitutes a pick-up device. The pick-up device may include the pick-up unit 20.

The wafer recognition camera 14 is used for finding a pick-up position of the dies D to be picked up from the wafer W or for inspecting the surface of the dies D.

The pick-up unit 20 has a pick-up head 21 and a Y drive unit 23. The pick-up head 21 is equipped with a collet 22 for adsorbing and holding the peeled die D at the tip thereof. The pick-up head 21 picks up the die D from the wafer supply unit 10 and places it on the intermediate stage 31. The Y drive unit 23 moves the pick-up head 21 in the Y1-Y2 direction. The pick-up unit 20 has respective drive units (not shown) for lifting or lowering, rotating, and X-direction moving of the pick-up head 21.

The intermediate stage unit 30 has an intermediate stage 31 on which the dies D are placed and a stage recognition camera 34 for recognizing the dies D on the intermediate stage 31. The intermediate stage 31 is equipped with a suction hole for adsorbing the dies D placed on the intermediate stage 31. The dies D placed on the intermediate stage 31 are temporarily held thereon. The intermediate stage 31 is not only a stage on which the dies D are placed but also a pick-up stage from which the dies D are picked up.

The bonding unit 40 has a bonding head 41, a Y drive unit 43, a substrate recognition camera 44, and a bonding stage 46. The bonding head 41 is equipped with a collet 42 for adsorbing and holding the die D at the edge thereof. The Y drive unit 43 moves the bonding head 41 in the Y1-Y2 direction. The substrate recognition camera 44 images a position recognition mark (not shown) of a substrate S and recognizes a bonding position. It is to be noted that the substrate S has a plurality of product areas (which will hereinafter be called “package areas P”) which will finally become one package. Each package area P has the position recognition mark. The bonding stage 46 is lifted when the die D is placed on the substrate S and supports the substrate S from below. The bonding stage 46 has a suction port (not shown) for the vacuum adsorption of the substrate S and is therefore capable of fixing the substrate S. The bonding stage 46 has a heating unit (not shown) for heating the substrate S. The bonding unit 40 has respective drive units (not shown) for lifting or lowering, rotating, and X-direction moving of the bonding head 41.

The bonding head 41 having such a constitution corrects the pick-up position or posture based on the imaged data of the stage recognition camera 34 and picks up a die D from the intermediate stage 31. Then, the bonding head 41 bonds the die onto the package area P of the substrate S based on an imaged data of the substrate recognition camera 44 or bonds in a form of stacking the die on the die already bonded onto the package area P of the substrate S.

The carrier unit 50 has a carrying claw 51 for seizing and carrying the substrate S and a carrying lane 52 in which the substrate S moves. The substrate S moves in the X direction by driving a nut, which is not shown, of the carrying claw 51 provided in the carrying lane 52 with a ball screw, which is not shown, provided along the carrying lane 52. According to such a constitution, the substrate S is moved along the carrying lane 52 from the substrate supply unit 60 to the bonding position and after bonding, the substrate S is moved to the substrate unloading unit 70 and is delivered to the substrate unloading unit 70.

The substrate supply unit 60 takes out the substrate S, which has been housed in a carrying jig and delivered, from the carrying jig and supplies it to the carrier unit 50. The substrate unloading unit 70 houses the substrate S, which has been carried by the carrier unit 50, in the carrying jig.

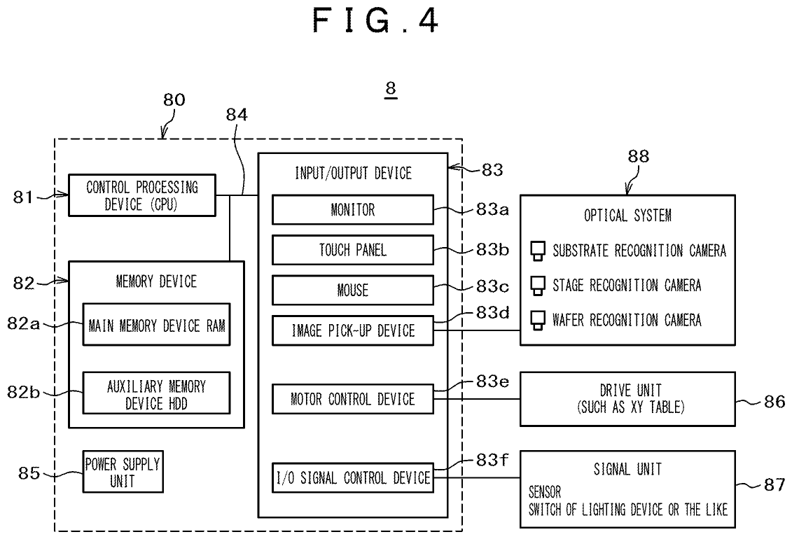

Next, the control unit 80 will be described referring to FIG. 4. FIG. 4 is a block diagram showing the schematic constitution of the die bonder control system shown in FIG. 1.

The control system 8 is equipped with a control unit (a control device or a controller) 80, a drive unit 86, a signal unit 87, an optical system 88, and the like. Roughly speaking, the control unit 80 has a control processing device 81 comprised mainly of a CPU (Central Processing unit), a memory device 82, an input/output device 83, a bus line 84, and a power supply unit 85. The memory device 82 has a main memory device 82a and an auxiliary memory device 82b. The main memory device 82a is comprised of a RAM (Random Access Memory) that stores therein a processing program and the like. The auxiliary memory device 82b is comprised of an HDD (Hard Disk Drive), an SSD (Solid State Drive), or the like that stores control data necessary for control, image data, and the like.

The input/output device 83 has: a monitor 83a that displays the condition of the device, information, and the like; a touch panel 83b that inputs the instruction from an operator; a mouse 83c that operates the monitor 83a; and an image pick-up device 83d that picks up the image data from the optical system 88. The input/output device 83 further has a motor control device 83e and an I/O signal control device 83f. The motor control device 83e controls the ZY drive shaft of an XY table (not shown) or a bond head table of the wafer supply unit 10, the drive unit of the push-up unit 13, and the like. The I/O signal control device 83f picks up or controls signals from the signal unit 87 including various sensors, switch and volume that control brightness of lighting devices. The optical system 88 includes the wafer recognition camera 14, the stage recognition camera 34, and the substrate recognition camera 44. The control processing device 81 picks up necessary data via the bus line 84, processes, and controls the pick-up head 21 and the like or sends information to the monitor 83a and the like.

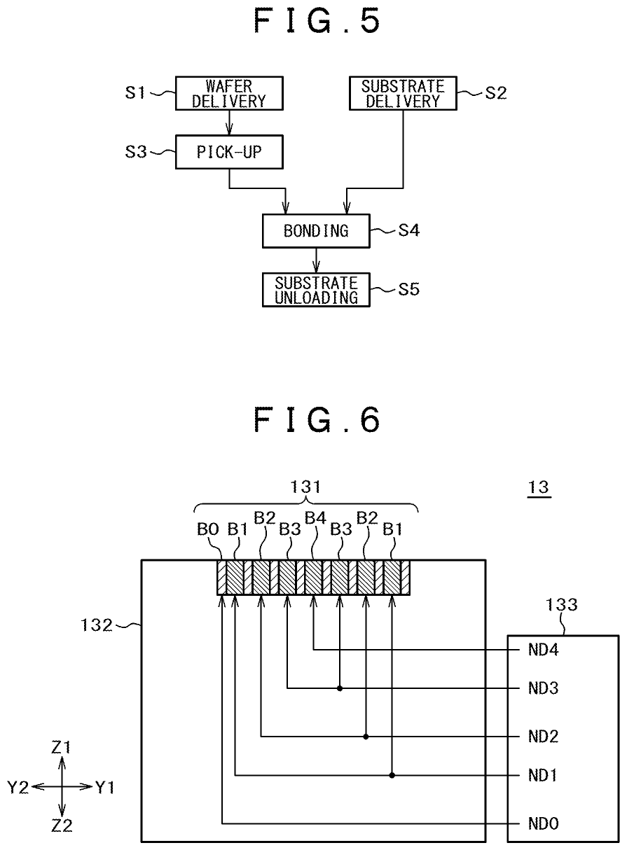

A part of the step of manufacturing a semiconductor device (method of manufacturing a semiconductor device) with the die bonder 1 will be described referring to FIG. 5. FIG. 5 is a flow chart showing the method of manufacturing a semiconductor device with the die bonder shown in FIG. 1. In the following description, the operation of the individual units constituting the die bonder 1 will be controlled by the control unit 80.

### (Wafer Delivery Step: Step S1)

Wafer rings WR are supplied to the wafer cassette of a wafer cassette lifter 11. The wafer rings WR thus supplied are supplied onto a wafer holder 12. It is to be noted that with respect to the wafer W, each die is inspected in advance with an inspection device such as prober, and wafer map data showing whether the die is good or bad is formed. This wafer map data is stored in a memory device of the control unit 80.

### (Substrate Delivery Step: Step S2)

A carrying jig having the substrate S housed therein is supplied to the substrate supply unit 60. The substrate S is taken out from the carrying jig at the substrate supply unit 60 and the substrate S is fixed to the carrying claw 51.

### (Pick-Up Step: Step S3)

After the step S1, the wafer holder 12 is moved to enable pick-up of a desired die D from the dicing tape DT. The die D is photographed by the wafer recognition camera 14 and based on an image data obtained by photographing, the positioning and surface inspection of the die D are carried out. By image processing of the image data, the amounts of deviation (in the X, Y, and 0 directions) of the die D on the wafer holder 12 from the die position reference point of the die bonder are calculated, followed by positioning. It is to be noted that with respect to the die position reference point, a predetermined position of the wafer holder 12 is retained as a default of the device. Surface inspection of the die D is performed by image processing of the image data.

After positioning of the die D, it is peeled from the dicing tape DT by the push-up unit 13 and the pick-up head 21. The die D peeled from the dicing tape DT is absorbed and held by the collet 22 provided on the pick-up head 21 and is carried and placed on the intermediate stage 31.

The die D on the intermediate stage 31 is photographed by the stage recognition camera 34 and based on the image data obtained by photographing, the positioning and surface inspection of the die D are performed. By image processing of the image data, the amounts of deviation (in the X, Y, and 0 directions) of the die D on the intermediate stage 31 from the die position reference point of the die bonder are calculated, followed by positioning. It is to be noted that with respect to the die position reference point, a predetermined position of the intermediate stage 31 is retained as a default of the device. Surface inspection of the die D is performed by image processing of the image data.

The pick-up head 21 that has carried the die D to the intermediate stage 31 is returned to the wafer supply unit 10. According to the aforesaid procedure, a next die D is peeled from the dicing tape DT. Thus, according to a similar procedure, the dies D will hereinafter be peeled pone by one from the dicing tape DT.

### (Bonding Step: Step S4)

The substrate S is carried to the bonding stage 46 by the carrier unit 50. The substrate S placed on the bonding stage 46 is photographed by the substrate recognition camera 44 and based on the image data obtained by photographing, the positioning and surface inspection of the substrate S are performed. By image processing of the image data, the amounts of deviation (in the X, Y, and 0 directions) of the substrate S from the substrate position reference point of the die bonder 1 are calculated. It is to be noted that with respect to the substrate position reference point, a predetermined position of the bonding unit 40 is retained as a default of the device. Surface inspection of the substrate S is performed by image processing of the image data.

An adsorption position of the bonding head 41 is corrected based on the deviation amounts of the die D on the intermediate stage 31 which have been calculated in the Step S3 and the die D is absorbed by the collet 42. By the bonding head 41 which has adsorbed the die D thereto from the intermediate stage 31, the die D is bonded to a predetermined position of the substrate S supported by the bonding stage 46. The term “predetermined position of the substrate S” as used herein means a package area P of the substrate S, a region on which the element has already been placed and to which the element is to be bonded in addition, or a region to which an element is to be stacked and bonded. The die D bonded to the substrate S is photographed with the substrate recognition camera 44, and based on the image data obtained by photographing, whether or not the die D is bonded to a desired position is inspected.

The bonding head 41 used for bonding the die D to the substrate S is returned to the intermediate stage 31. According to the aforesaid procedure, a next die D is picked up from the intermediate stage 31 and bonded to the substrate S. This procedure is repeated to bond a die D to all the package areas P of the substrate S.

### (Substrate Unloading Step: Step S5)

The substrate S having the die D bonded thereto is carried in the substrate unloading unit 70. The substrate S is taken out from the carrying claw 51 at the substrate unloading unit 70 and is housed in the carrying jig. The carrying jig having the substrate S housed therein is unloaded from the die bonder 1.

As described above, the die D is mounted on the substrate S and unloaded from the die bonder 1. Then, for example, the carrying jig in which the substrate S having the die D mounted thereon has been housed is carried to a wire bonding step, and an electrode of the die D is electrically connected to an electrode of the substrate S via an Au wire or the like. Then, the substrate S is carried to a molding step. The die D and the Au wire are sealed with a molding resin (not shown) to complete a semiconductor package.

When stacking and bonding are performed, the wire bonding step is followed by delivering, to the die bonder, of a carrying jig in which the substrate S having the die D mounted thereon has been placed and housed and stacking of another die D on the die D mounted on the substrate S. After unloaded from the die bonder, the stacked die is electrically connected with an electrode of the substrate S via an Au wire in the wire bonding step. The dies on and above the second level are peeled from the dicing tape DT by the aforesaid method, carried to the bonding unit, and then stacked on the die D. After repetition of the aforesaid step a predetermined number of times, the substrate S is carried to the molding step. A plurality of dies D and an Au wire are sealed with a molding resin (not shown) to complete a stacked package.

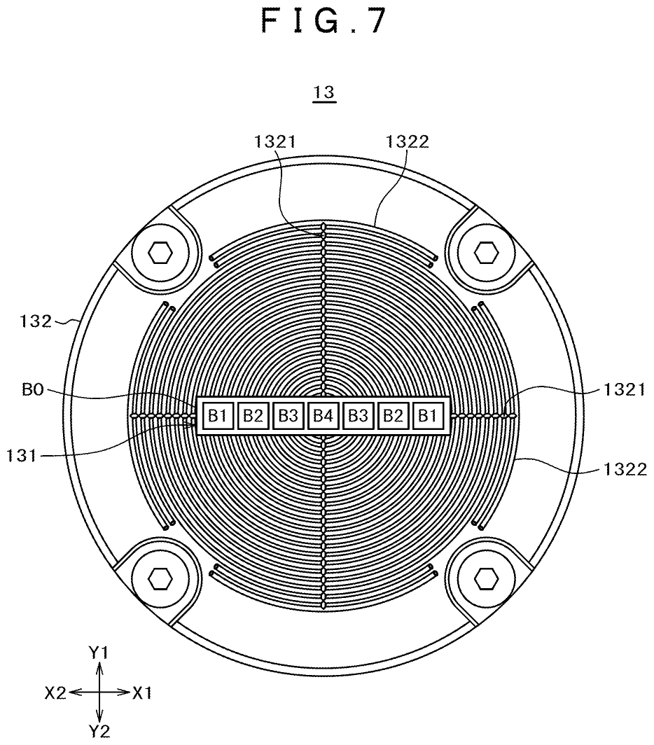

Next, the push-up unit 13 will be described referring to FIGS. 6 and 7. FIG. 6 schematically shows the cross-section of the main portion of the push-up unit shown in FIG. 2. FIG. 7 is a top view of the push-up unit shown in FIG. 6.

In the push-up unit 13, a cylindrical dome 132 has a block unit 131. The dome 132 has, at the periphery on the upper surface thereof, a plurality of suction ports 1321 and a plurality of grooves 1322 for connecting the plurality of suction ports 1321. When the push-up unit 13 is lifted to bring the upper surface thereof into contact with the back surface of a dicing tape DT, the pressure inside the suction port 1321 is reduced by a suction mechanism which is not shown. At this time, the back surface of the dicing tape DT is suctioned downward and closely adheres to the upper surface of the dome 132.

In the center portion of the dome 132, the block unit 131 having blocks B0 to B4 that push up the dicing tape DT is incorporated. The block B0 is a quadrangular prism and has a plurality of quadrangular openings that penetrate in the Z1-Z2 direction. The blocks B1 to B4 are each a quadrangular prism and are placed in the opening of the block B0. The blocks B1 to B4 are quadrangular in a planar view.

The block B0 has a circumference equal to or slightly larger than the circumference of the die D. In other words, the Y1-Y2 direction length (length of the short-side direction or width) of the block B0 is substantially equal to the Y1-Y2 direction length (length of the short-side direction or width) of the die D, while the X1-X2 direction length (length of the long-side direction) of the block B0 is substantially equal to the X1-X2 direction length (length of the long-side direction) of the die D.

As shown in FIG. 6, the blocks B0 to B4 independently move vertically by means of drive shafts ND0 to ND4 of the drive unit 133. The drive unit 133 is equipped with four sets of a motor which is not shown and a plunger mechanism that converts the rotation of the motor into vertical movement by means of a cum or link and gives vertical movement to the drive shafts ND0 to ND4.

A setting method and control of the operation of the push-up unit 13 will hereinafter be described.

The control unit 80 is constituted to control, based on a time chart recipe, the drive shafts ND0 to ND4 that drive the blocks B0 to B4, respectively. With respect to the operation of the blocks B0 to B4 of the push-up unit 13, the time required for a step, the lifting or lowering speed of the block, and the height (position) of the block for each block or each step are set in the time chart recipe.

A plurality of time chart recipes different in setting item is prepared in advance, and a user selects one from the time chart recipes by GUI (Graphical User Interface) and inputs a set value in the item of the selected time chart recipe. Alternatively, the user may perform data communication of the time chart recipe to which the set value has been input in advance to a semiconductor manufacturing device such as die bonder from an external apparatus or install it in the semiconductor manufacturing device from an external memory device. The external memory device is, for example, a magnetic tape, a magnetic disk such as flexible disk or hard disk, an optical disk such as CD or DVD, a magneto-optical disk such as MO, a semiconductor memory such as USB memory or memory card.

As described above, by the setting of the time chart recipe, the operation of the individual blocks B0 to B4 of the push-up unit 13 can be set freely in the push-up operation step, and various operations of the push-up unit 13 can be performed.

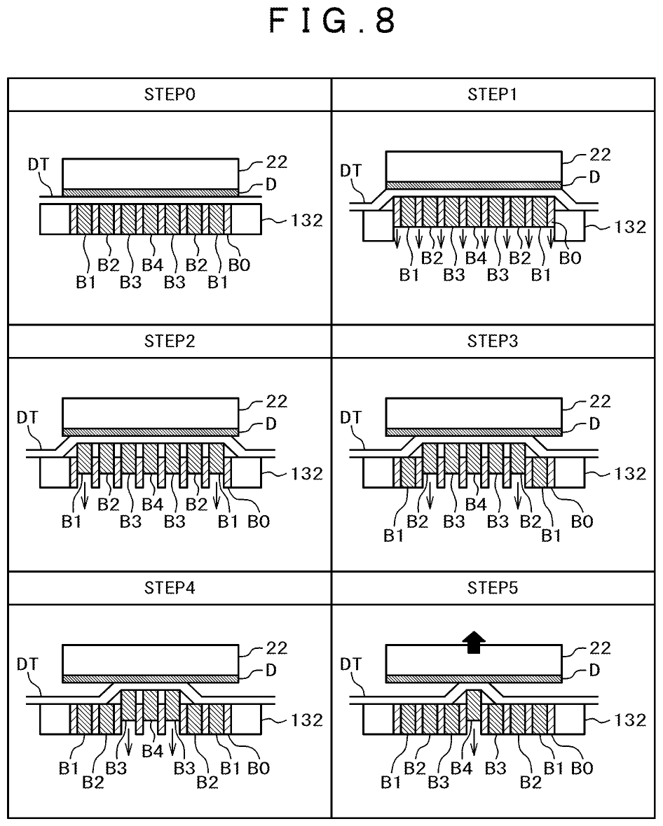

The operation examples of the push-up unit 13 will be described referring to FIG. 8. FIG. 8 is a view for describing a push-up sequence in one operation example of the push-up unit shown in FIG. 6.

### (0th Step: Step 0)

The pick-up operation is started by positioning an intended die D, which is present on the dicing tape DT, at the push-up unit 13 and the collet 22. When the positioning is completed, the control unit 80 adsorbs the dicing tape DT to the upper surface of the push-up unit 13 by vacuuming via the suction port 1321 of the push-up unit 13 and the gap of the blocks B0 to B4. At this time, the upper surface of the blocks B0 to B4 is at the same height (initial position) as the upper surface of the dome 132. The control unit 80 supplies, under such a state, vacuum from a vacuum supply source which is not shown, and lowers and lands the collet 22 toward the device surface of the die D while vacuum drawing.

### (First Step: Step 1)

Then, the control unit 80 simultaneously lifts the blocks B0 to B4 to a predetermined height (H2) at a predetermined speed (s1). Here, the die D is lifted while being sandwiched between the collet 22 and the blocks B0 to B4, but the peripheral portion of the dicing tape DT has still been vacuum-adsorbed to the suction port 1321 of the dome 132 which is the periphery of the push-up unit 13 so that there occurs tension at the periphery of the die D. As a result, peeling of the dicing tape DT is started at the periphery of the die D.

### (Second Step: Step 2)

Subsequently, the control unit 80 lowers the block B0 to a height equal to that of the upper surface of the dome 132 at a predetermined speed (s2).

### (Third Step: Step 3)

Subsequently, the control unit 80 lowers the block B1 to a height equal to that of the upper surface of the dome 132 at the predetermined speed (s2). Here, since the block B1 is lowered to the height equal to that of the upper surface of the dome 132, the dicing tape DT loses its support and due to the tension of the dicing tape DT, peeling of the dicing tape DT progresses further.

### (Fourth Step: Step 4)

Subsequently, the control unit 80 lower the block B2 to a height equal to that of the upper surface of the dome 132 at the predetermined speed (s2). Here, since the block B2 is lowered to the height equal to that of the upper surface of the dome 132, the dicing tape DT loses its support and due to the tension of the dicing tape DT, peeling of the dicing tape DT progresses further.

### (Fifth Step: Step 5)

Subsequently, the control unit 80 lowers the block B3 to a height equal to that of the upper surface of the dome 132 at the predetermined speed (s2). Here, since the block B3 is lowered to the height equal to that of the upper surface of the dome 132, the dicing tape DT loses its support and due to the tension of the dicing tape DT, peeling of the dicing tape DT progresses further.

Subsequently, the control unit 80 lifts up the collet 22 and at the same time, lowers the block B4 at a predetermined speed (s3) and returns it to the initial position. As a result, the peeling work of the die D from the dicing tape DT is completed.

The aforesaid push-up sequence (operation) will hereinafter be called RMS (Reverse Multi Step).

The push-up unit 13 is applicable to a die having a high aspect ratio, for example, an aspect ratio of 5:1 or higher. It is applicable, for example, to a die for an LCD (liquid crystal display) driver. Even if the aspect ratio is less than 5:1, the unit is applicable to a die having a narrow short-side length (width).

Supposing that the width (overhang amount) of an external flame at which the block B0 is brought into contact with the dicing tape DT is about 0.2 mm and the Y1-Y2 direction length (width) of the blocks B1 to B4 is 0.1 mm or more, the unit is applicable to a die having a minimum width of about 0.6 mm when the gap between the blocks is taken into consideration. Since the push-up block has two stages in the Y1-Y2 direction, it is preferred not to increase the width of the blocks B1 to B4 excessively and for example, the width is preferably 1.5 mm or less. In this case, the maximum width of the die is about 2 mm.

According to the present embodiment, pushing-up with two or more stages can be performed even if the push-up blocks have a narrow short-side length (width) so that this makes it possible to reduce the damage of a die having a small width during pushing-up of the die. Pushing-up of more stages of blocks can be performed for long side and an overhang can be reduced when the outside block is lowered. This therefore makes it possible to reduce the damage (failure) such as cracking or chipping of the die. The term “overhang” as used herein means that the periphery of the die D protrudes outside from the end portion of the outermost block which is in contact with the dicing tape DT.

### MODIFICATION EXAMPLES

Some representative modification examples of the embodiment will hereinafter be given. In the following description of the modification examples, portions having a constitution or function similar to that described in the aforesaid embodiment will be identified by reference numerals similar to those used in the aforesaid embodiment. In the description on these portions, the description in the embodiment can be applied as needed to the extent that it is not technically inconsistent. In addition, a portion of the aforesaid example and all or part of the plurality of modification examples can be used in combination as needed to the extent that it is not technically inconsistent.

### First Modification Example

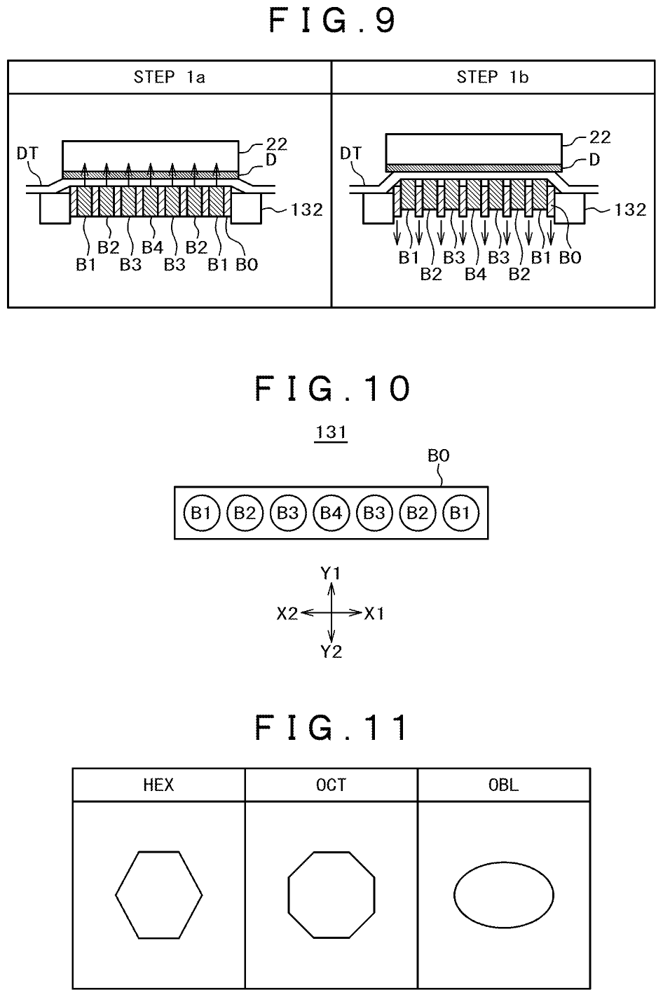

FIG. 9 is a view for describing the push-up sequence in First Modification Example of the push-up unit shown in FIG. 6.

The push-up sequence in First Modification Example is similar to that of the embodiment except for the first step (STEP 1).

In the push-up sequence in First Modification Example, the control unit 80 stops the block B0 at a predetermined height (H1) (STEP 1a) and lifts the blocks B1 to B4 to the predetermined height (H2) (Step 1b). When the block B0 is functioned as a peeling starting point, the aforesaid sequence makes it possible not to increase a step difference at the time of lifting the blocks B1 to B4 thereafter and thereby reduce the deformation of a die D to be peeled and also the deformation of dies therearound. As a result, the stress on the die D to be peeled and the dies D therearound can be made smaller and therefore, they can be prevented from damage such as cracking or chipping.

It is also preferred to lower the block B0 while lifting the blocks B1 to B4 from H1 to H2. This makes it possible to increase the peeling speed of the die D.

### Second Modification Example

FIG. 10 is a top view of the block unit of the push-up unit according to Second Modification Example.

In the embodiment, the inside blocks B1 to B4 are quadrangular in a planar view. On the other hand, in Second Modification Example, the inside blocks B1 to B4 are circular in a planar view. The inside blocks B1 to B4 are columnar blocks.

Since the inside blocks B1 to B4 are changed to have a columnar shape, their diameter can be reduced to about 0.6 mm. This means that the width of the blocks B1 to B4 can be made smaller than that in the embodiment.

### Third Modification Example

FIG. 11 is a top view of an inside block in Third Modification Example.

The shape of the inside blocks B1 to B4 in planar view may be, as shown in FIG. 11, polygonal such as hexagonal or octagonal, or oblong. When they have a polygonal shape (including the quadrangular shape of the embodiment), it is preferred to provide the corner thereof with a curved surface. This makes it possible to prevent the damage of the blocks due to a burr on the corner.

### Fourth Modification Example

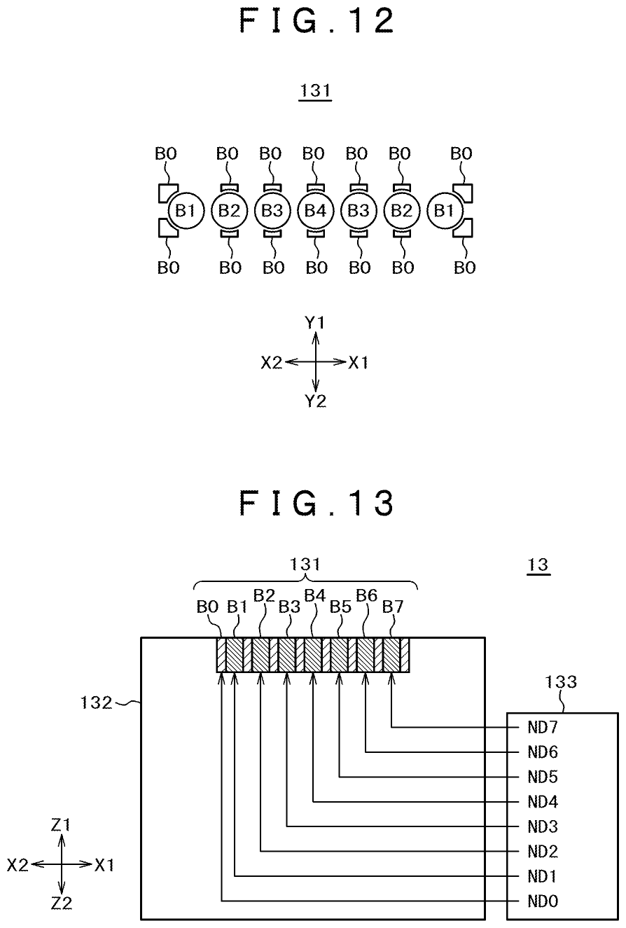

FIG. 12 is a top view of the block unit of a push-up unit in Fourth Modification Example.

In Second Modification Example, the outside block B0 has a plurality of openings and the outside block B0 surrounds all the side surfaces of the inside blocks B1 to B4 therewith. In Fourth Modification Example, on the other hand, the outside block B0 has one opening and the outside block B0 and the dicing tape DT form a discontinuous or intermittent contact surface. The block B1 has, on the side surface thereof, the block B0 in the vicinity of the four corners made of the long sides and short sides of the die D. The block B0 is present only at the side surface of the blocks B2 to B4 on the side surface of the long side of the die D. This makes it possible to selectively form a peeling starting point in the vicinity of the blocks B1 to B4 or the like when the block B0 is lowered.

### Fifth Modification Example

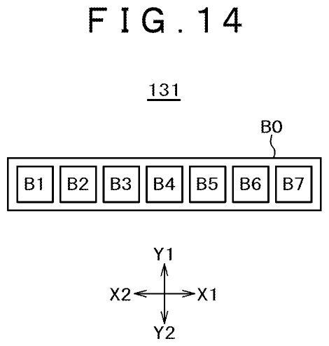

The constitution of a push-up unit 13 according to Fifth Modification Example will be described referring to FIGS. 13 and 14. FIG. 13 is a view schematically showing the cross-section of the main portion of a push-up unit in Fifth Modification Example. FIG. 14 is a top view of the block unit of the push-up unit shown in FIG. 13.

In the embodiment, described was an example of seven inside blocks comprised of four blocks B1 to B4 different in operation. On the other hand, in Fifth Modification Example, inside seven blocks are comprised of seven blocks B1 to B7 different in operation. The blocks B1, B2, B3, B4, B5, B6, and B7 are placed in order of mention from the X2 side to the X1 side. In Fifth Modification Example, the blocks B0 to B7 are moved vertically by means of drive shafts ND0 to ND7. The drive unit 133 is equipped with eight sets of motors and plunger mechanisms for converting rotational movement of the motors to a vertical movement with a cum or link, which are not shown, and it gives the vertical movement to the drive shafts ND0 to ND7.

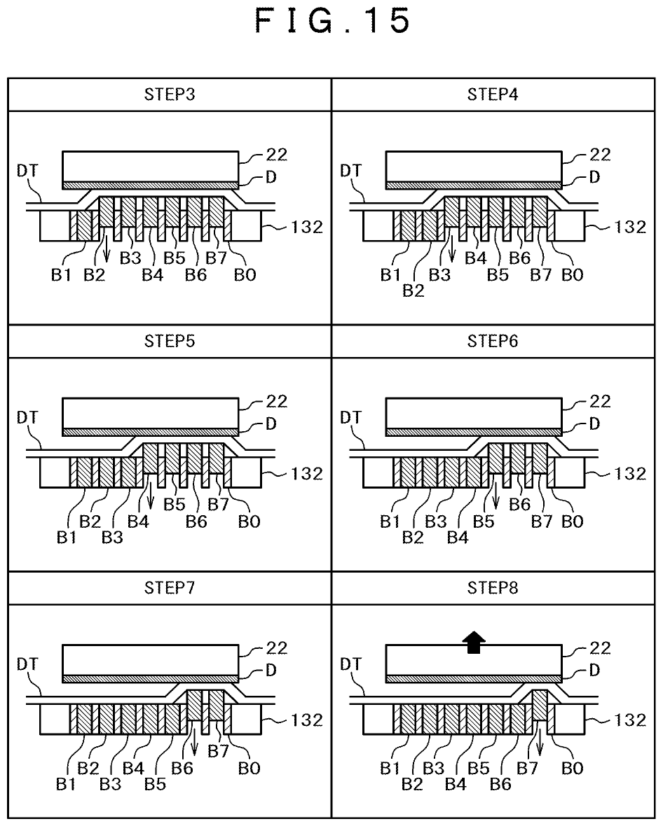

An operation example of the push-up unit 13 in Fifth Modification Example is described referring to FIG. 15. FIG. 15 is a view for describing the push-up sequence of the push-up unit shown in FIG. 13.

In the steps from the 0th step (Step 0) to the second step (Step 2), operations similar to those in the push-up sequence of the embodiment shown in FIG. 8 is performed.

### (Third Step: Step 3)

Subsequently, the control unit 80 lowers the block B1 at the predetermined speed (s2) until it reaches a height equal to that of the upper surface of the dome 132. Here, since the block B1 is lowered to the height equal to that of the upper surface of the dome 132, the dicing tape DT loses its support and due to the tension of the dicing tape DT, peeling of the dicing tape DT progresses further.

### (Fourth Step: Step 4)

Subsequently, the control unit 80 lowers the block B2 to a height equal to that of the upper surface of the dome 132 at the predetermined speed (s2). Here, since the block B2 is lowered to the height equal to that of the upper surface of the dome 132, the dicing tape DT loses its support and due to the tension of the dicing tape DT, peeling of the dicing tape DT progresses further.

### (Fifth Step: Step 5)

Subsequently, the control unit 80 lowers the block B3 to a height equal to that of the upper surface of the dome 132 at the predetermined speed (s2). Here, since the block B3 is lowered to the height equal to that of the upper surface of the dome 132, the dicing tape DT loses its support and due to the tension of the dicing tape DT, peeling of the dicing tape DT progresses further.

### (Sixth Step: Step 6)

Subsequently, the control unit 80 lowers the block B4 to a height equal to that of the upper surface of the dome 132 at the predetermined speed (s2). Here, since the block B4 is lowered to the height equal to that of the upper surface of the dome 132, the dicing tape DT loses its support and due to the tension of the dicing tape DT, peeling of the dicing tape DT progresses further.

### (Seventh Step: Step 7)

Subsequently, the control unit 80 lowers the block B5 to a height equal to that of the upper surface of the dome 132 at the predetermined speed (s2). Here, since the block B5 is lowered to the height equal to that of the upper surface of the dome 132, the dicing tape DT loses its support and due to the tension of the dicing tape DT, peeling of the dicing tape DT progresses further.

### (Eighth Step: Step 8)

Subsequently, the control unit 80 lowers the block B6 to a height equal to that of the upper surface of the dome 132 at the predetermined speed (s2). Here, since the block B6 is lowered to the height equal to that of the upper surface of the dome 132, the dicing tape DT loses its support and due to the tension of the dicing tape DT, peeling of the dicing tape DT progresses further.

Subsequently, the control unit 80 lifts the collet 22 upward and at the same time, lowers the block B7 at the predetermined speed (s3) and returns it to the original position, by which the peeling work of the die D from the dicing tape DT is completed.

Fifth Modification Example makes it possible to peel the die by a slide operation in which the inside blocks work successively from one end to the other end. It is to be noted that the RMS operation of the embodiment may also be performed in Fifth Modification Example.

### Sixth Modification Example

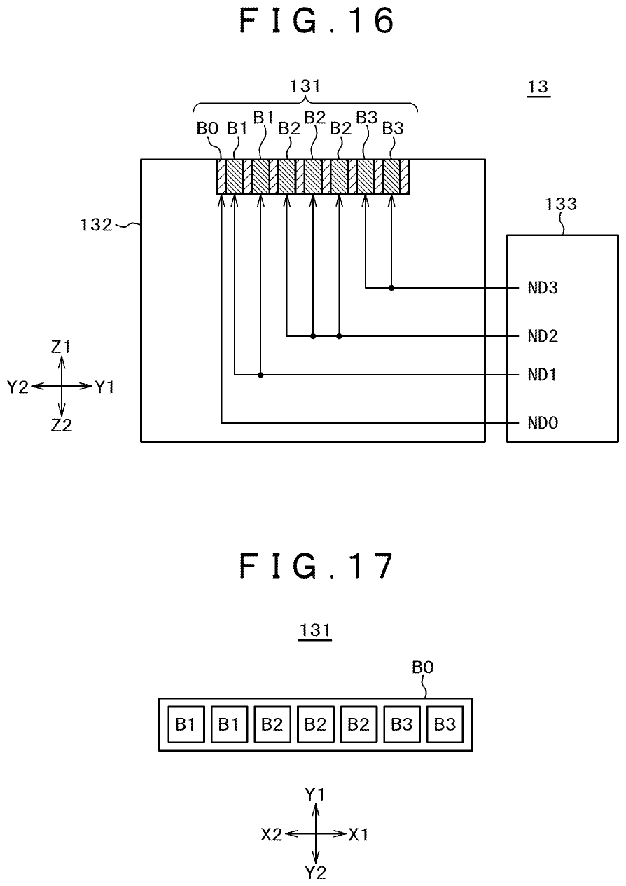

FIG. 16 is a view schematically showing the cross-section of the main portion of a push-up unit in Sixth Modification Example. FIG. 17 is a top view of the block unit shown in FIG. 16.

In Fifth Modification Example, described was an example of seven inside blocks respectively comprised of the seven blocks B1 to B7 different in operation. On the other hand, in Sixth Modification Example, seven inside blocks are comprised of three blocks B1, B2, and B3 different in operation. The blocks B1, B1, B2, B2, B2, B3, and B3 are placed successively in order of mention from the X2 side to the X1 side. In Sixth Modification Example, the blocks B0 to B3 are vertically moved by means of the drive shafts ND0 to ND3.

The operation of the push-up unit 13 in Sixth Modification Example will next be described. The operation of the push-up unit 13 is similar to that of the embodiment shown in FIG. 8 from the 0th step (Step 0) to the second step (STEP 2) of the push-up sequence.

### (Third Step: Step 3)

Subsequently, the control unit 80 lowers the block B1 to a height equal to that of the upper surface of the dome 132 at the predetermined speed (s2). Here, since the block B1 is lowered to the height equal to that of the upper surface of the dome 132, the dicing tape DT loses its support and due to the tension of the dicing tape DT, peeling of the dicing tape DT progresses further.

### (Fourth Step: Step 4)

Subsequently, the control unit 80 lower the block B2 to a height equal to that of the upper surface of the dome 132 at the predetermined speed (s2). Here, since the block B2 is lowered to the height equal to that of the upper surface of the dome 132, the dicing tape DT loses its support and due to the tension of the dicing tape DT, peeling of the dicing tape DT progresses further.

Then, the control unit 80 lifts the collet 22 upward and at the same time, lowers the block B3 at the predetermined speed (s3) and returns it to the initial position. As a result, the peeling work of the die D from the dicing tape DT is completed.

In Sixth Modification Example, since the inside blocks adjacent to each other form a group, the number of drive shafts can be reduced.

### Seventh Modification Example

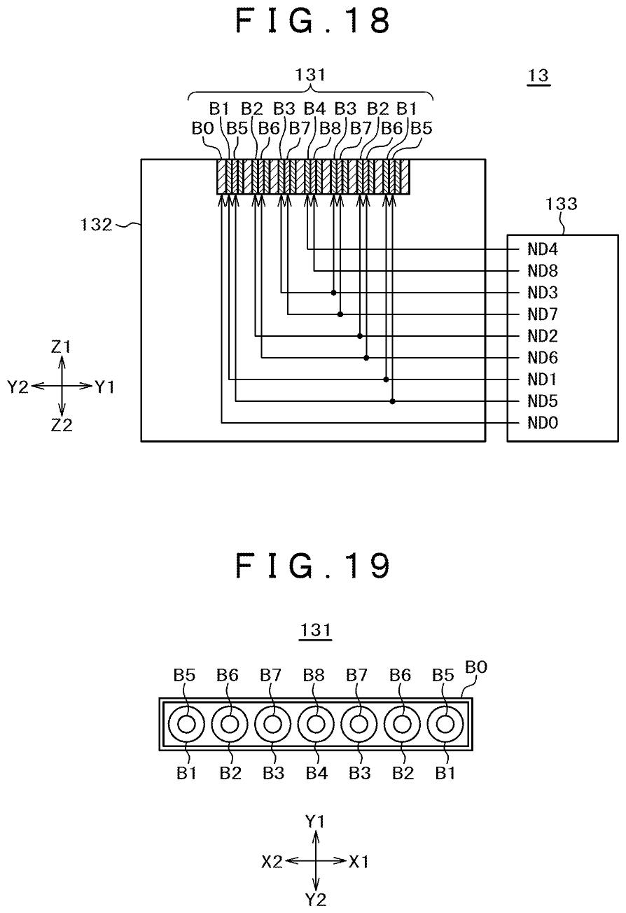

FIG. 18 is a view schematically showing the cross-section of the main portion of a push-up unit in Seventh Modification Example. FIG. 19 is a top view of the block unit of the push-up unit shown in FIG. 18.

In Third Modification Example, the inside blocks B1 to B4 are columnar ones. In Seventh Modification Example, on the other hand, the inside blocks B1 to B4 are cylindrical ones (pipes) and they have blocks B5 to B8 therein. The blocks B5 to B8 are columnar ones (pins). For example, thin pipe-shaped blocks B1 to B4 are constituted by concentrically inserting therein ultrafine pin-shaped blocks B5 to B8. In Seventh Modification Example, the blocks B0 to B8 are vertically moved by means of the drive shafts ND0 to ND8.

The push-up unit 13 in Seventh Modification Example performs an RMS operation. In Seventh Modification Example, an operation from the 0th step (Step 0) to the second step (STEP 2) is similar to that from the 0th step (Step 0) to the second step (STEP 2) of the push-up sequence of the embodiment shown in FIG. 8. The blocks B5 to B8 of in Seventh Modification Example however operate similarly to the blocks B1 to B4 of the embodiment.

An operation from the third step (STEP 3) to the fifth step (STEP 5) in Seventh Modification Example is similar to that from the third step (STEP 3) to the fifth step (STEP 5) of the push-up sequence of the embodiment shown in FIG. 8.

### (Sixth Step: Step 6)

Subsequently, the control unit 80 lowers the block B5 to a height equal to that of the upper surface of the dome 132 at the predetermined speed (s2). Here, since the block B5 is lowered to the height equal to that of the upper surface of the dome 132, the dicing tape DT loses its support and due to the tension of the dicing tape DT, peeling of the dicing tape DT progresses further.

### (Seventh Step: Step 7)

Subsequently, the control unit 80 lowers the block B6 to a height equal to that of the upper surface of the dome 132 at the predetermined speed (s2). Here, since the block B6 is lowered to the height equal to that of the upper surface of the dome 132, the dicing tape DT loses its support and due to the tension of the dicing tape DT, peeling of the dicing tape DT progresses further.

### (Eighth Step: Step 8)

Subsequently, the control unit 80 lowers the block B7 to a height equal to that of the upper surface of the dome 132 at the predetermined speed (s2). Here, since the block B7 is lowered to the height equal to that of the upper surface of the dome 132, the dicing tape DT loses its support and due to the tension of the dicing tape DT, peeling of the dicing tape DT progresses further.

Subsequently, the control unit 80 lifts the collet 22 upward and at the same time, lowers the block B8 at the predetermined speed (s3) and returns it to the original position, by which the peeling work of the die D from the dicing tape DT is completed.

An overhang can be reduced because the number of the stages of the blocks in the Y1-Y2 direction of the block unit 131 is larger than that in the embodiment.

### Eighth Modification Example

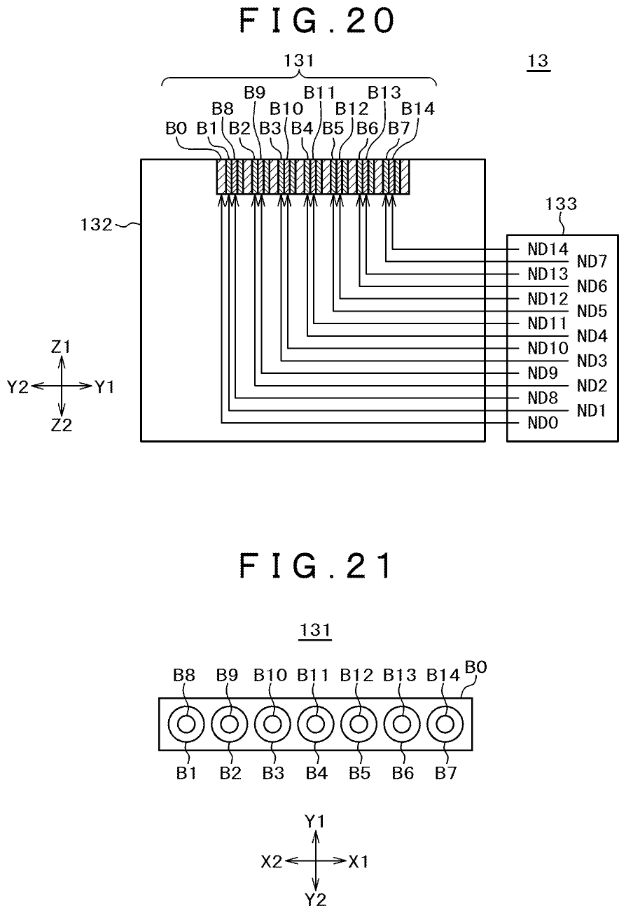

FIG. 20 is a view schematically showing the cross-section of the main portion of a push-up unit in Eighth Modification Example. FIG. 21 is a top view of the block unit of the push-up unit shown in FIG. 20.

In Seventh Modification Example, described was an example of fourteen inside blocks comprised of eight blocks B1 to B8 different in operation. On the other hand, in Eighth Modification Example, the fourteen inside blocks are comprised of fourteen blocks B1 to B14 different in operation, respectively. The blocks B1, B2, B3, B4, B5, B6, and B7 are placed in order of mention from the X2 side to the X1 side. The blocks B1 to B7 have therein blocks B8 to B14, respectively. In Eighth Modification Example, the blocks B0 to B14 are moved vertically by means of drive shafts ND0 to ND14.

Different from Seventh Modification Example, the push-up unit 13 in Eighth Modification Example performs a slide operation similar to that of Fifth Modification Example. The operation of the push-up unit 13 in Eighth Modification Example will next be described.

The operation in the 0th step (STEP 0) to the second step (STEP 2) in Eighth Modification example is similar to that in the 0th step (STEP 0) to the second step (STEP 2) of the push-up sequence by the push-up unit 13 in Fifth Modification example shown in FIG. 13. The operation of the blocks B8 to B14 in Eighth Modification example is however similar to that of the blocks B1 to B7 in Fifth Modification example.

The operation in the third step (STEP 3) to the eighth step (STEP 8) in Eighth Modification Example is similar to that in the third step (STEP 3) to the eighth step (STEP 8) of the push-up sequence of Fifth Modification Example shown in FIG. 15.

### (Ninth Step: Step 9)

Subsequently, the control unit 80 lowers the block B8 to a height equal to that of the upper surface of the dome 132 at the predetermined speed (s2). Here, since the block B8 is lowered to the height equal to that of the upper surface of the dome 132, the dicing tape DT loses its support and due to the tension of the dicing tape DT, peeling of the dicing tape DT progresses further.

### (Tenth Step: Step 10)

Subsequently, the control unit 80 lowers the block B9 to a height equal to that of the upper surface of the dome 132 at the predetermined speed (s2). Here, since the block B9 is lowered to the height equal to that of the upper surface of the dome 132, the dicing tape DT loses its support and due to the tension of the dicing tape DT, peeling of the dicing tape DT progresses further.

### (Eleventh Step: Step 11)

Subsequently, the control unit 80 lowers the block B10 to a height equal to that of the upper surface of the dome 132 at the predetermined speed (s2). Here, since the block B10 is lowered to the height equal to that of the upper surface of the dome 132, the dicing tape DT loses its support and due to the tension of the dicing tape DT, peeling of the dicing tape DT progresses further.

### (Twelfth Step: Step 12)

Subsequently, the control unit 80 lowers the block B11 to a height equal to that of the upper surface of the dome 132 at the predetermined speed (s2). Here, since the block B11 is lowered to the height equal to that of the upper surface of the dome 132, the dicing tape DT loses its support and due to the tension of the dicing tape DT, peeling of the dicing tape DT progresses further.

### (Thirteenth Step: Step 13)

Subsequently, the control unit 80 lowers the block B12 to a height equal to that of the upper surface of the dome 132 at the predetermined speed (s2). Here, since the block B12 is lowered to the height equal to that of the upper surface of the dome 132, the dicing tape DT loses its support and due to the tension of the dicing tape DT, peeling of the dicing tape DT progresses further.

### (Fourteenth Step: Step 14)

Subsequently, the control unit 80 lowers the block B13 to a height equal to that of the upper surface of the dome 132 at the predetermined speed (s2). Here, since the block B13 is lowered to the height equal to that of the upper surface of the dome 132, the dicing tape DT loses its support and due to the tension of the dicing tape DT, peeling of the dicing tape DT progresses further.

Subsequently, the control unit 80 lifts the collet 22 upward and at the same time, lowers the block B14 at the predetermined speed (s3) and returns it to the initial position. As a result, the peeling work of the die D from the dicing tape DT is completed.

An overhang can be reduced because the number of the stages of the blocks of the block unit 131 in the Y1-Y2 direction is larger than that in the embodiment.

### Ninth Modification Example

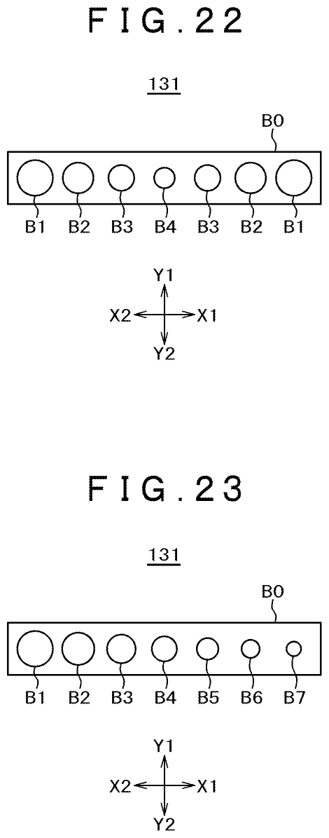

FIG. 22 is a top view of the block unit of a push-up unit in Ninth Modification Example.

In Second Modification Example, the inside blocks B1 to B4 are columnar ones having the same diameter. In Ninth Modification Example, on the other hand, the diameter (size) of the inside blocks B1 to B4 is made smaller in the following order: B1, B2, B3, and B4. In Ninth Modification Example, the push-up unit 13 performs an RMS operation so that an overhang amount can be changed (can be increased) with the progress of the peeling of the die D from the dicing tape DT.

### Tenth Modification Example

FIG. 23 is a top view of the block unit of a push-up unit in Tenth Modification Example.

In Ninth Modification Example, the push-up unit performs an RMS operation. In Tenth Modification Example, on the other hand, it performs a slide operation. In Tenth Modification Example, the inside blocks B1 to B7 are placed from the X2 side to the X1 side in the order of blocks B1, B2, B3, B4, B5, B6, and B7. In Tenth Modification Example, the diameter (size) of the inside blocks B1 to B7 is made smaller in the following order: the blocks B1, B2, B3, B4, B5, B6, and B7. This makes it possible to change (increase) an overhang amount with the progress of the peeling of the die D from the dicing tape DT.

### Eleventh Modification Example

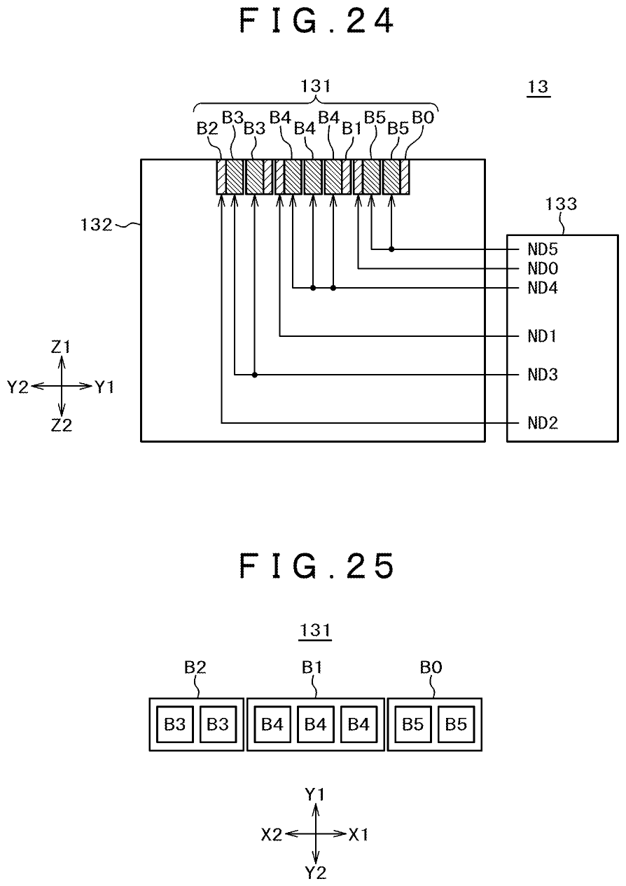

FIG. 24 is a view schematically showing the cross-section of the main portion of a push-up unit in Eleventh Modification Example. FIG. 25 is a top view of the block unit of the push-up unit shown in FIG. 24.

In Sixth Modification Example, the blocks B1 to B3 are placed inside one outside block B0. In Eleventh Modification Example, on the other hand, the outside block B0 is divided into three respective groups for the inside blocks B3 to B5 and is comprised of blocks B0, B1, and B2. The blocks B0, B1, and B2 each have one opening and are placed along the X1-X2 direction. The outside block B0 surrounds the two B5 blocks therewith, the outside block B1 surrounds the three B4 blocks therewith, and the outside block B2 surrounds the two blocks B3 therewith. In Eleventh Modification Example, the blocks B0 to B5 are moved vertically by means of the drive shafts ND0 to ND5.

The operation of the push-up unit 13 in Eleventh Modification Example will next be described. The operation in the 0th step (STEP 0) and the first step (STEP 1) in Eleventh Modification Example is similar to that in the 0th step (STEP 0) and the first step (STEP 1) in Sixth Modification Example. The operation of the blocks B0 to B2 in Eleventh Modification Example is however similar to that of the block B0 in Sixth Modification Example. The operation of the blocks B3 to B5 in Eleventh Modification Example is similar to that of the blocks B1 to B3 in Sixth Modification Example.

### (Second Step: Step 2)

Subsequently, the control unit 80 lowers the block B0 to a height equal to that of the upper surface of the dome 132 at the predetermined speed (s2).

### (Third Step: Step 3)

Subsequently, the control unit 80 lowers the block B1 to a height equal to that of the upper surface of the dome 132 at the predetermined speed (s2).

### (Fourth Step: Step 4)

Subsequently, the control unit 80 lowers the block B2 to a height equal to that of the upper surface of the dome 132 at the predetermined speed (s2).

### (Fifth Step: Step 5)

Subsequently, the control unit 80 lowers the block B3 to a height equal to that of the upper surface of the dome 132 at the predetermined speed (s2). Here, since the block B3 is lowered to the height equal to that of the upper surface of the dome 132, the dicing tape DT loses its support and due to the tension of the dicing tape DT, peeling of the dicing tape DT progresses further.

### (Sixth Step: Step 6)

Subsequently, the control unit 80 lowers the block B4 to a height equal to that of the upper surface of the dome 132 at the predetermined speed (s2). Here, since the block B4 is lowered to the height equal to that of the upper surface of the dome 132, the dicing tape DT loses its support and due to the tension of the dicing tape DT, peeling of the dicing tape DT progresses further.

Subsequently, the control unit 80 lifts the collet 22 upward and at the same time, lowers the block B5 at the predetermined speed (s3) and returns it to the initial position. As a result, the peeling work of the die D from the dicing tape DT is completed.

As a result, with the progress in the peeling, a peripheral peeling-starting point can be created at multiple timings.

### Twelfth Modification Example

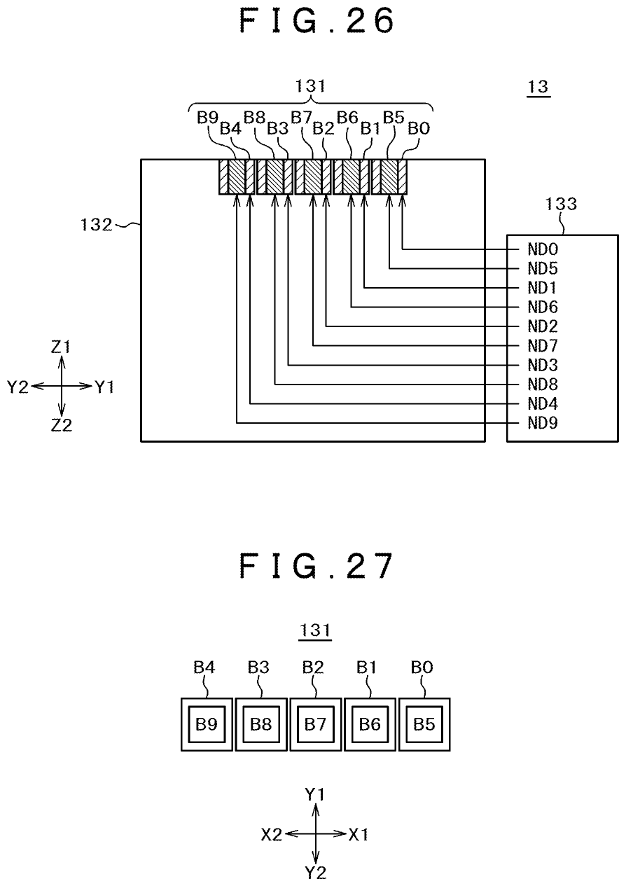

FIG. 26 is a view schematically showing the cross-section of the main portion of a push-up unit in Twelfth Modification Example. FIG. 27 is a top view of the block unit of the push-up unit shown in FIG. 26.

In Eleventh Modification Example, the outside block B0 surrounds the two blocks B5 therewith, the outside block B1 surrounds the three blocks B4 therewith, and the outside block B2 surrounds the two blocks B3 therewith. In Twelfth Modification Example, on the other hand, an outside block B0 surrounds one block B5 therewith and an outside block B1 surrounds one block B6 therewith. An outside block B2 surrounds one block B7 therewith, an outside block B3 surrounds one block B8 therewith, and an outside block B4 surrounds one block B9 therewith. In Twelfth Modification Example, the blocks B0 to B9 are moved vertically by means of drive shafts ND0 to ND9.

The operation of the push-up unit 13 in Twelfth Modification Example will next be described. An operation in the 0th step (STEP 0) and the first step (STEP 1) in Twelfth Modification Example is similar to that in the 0th step (STEP 0) and the first step (STEP 1) in Fifth Modification Example. However, the operation of the blocks B0 to B4 in Twelfth Modification Example is similar to that of the block B0 in Fifth Modification Example and the operation of the blocks B5 to B9 in Twelfth Modification Example is similar to that of the blocks B1 to B7 in Fifth Modification Example.

### (Second Step: Step 2)

Subsequently, the control unit 80 lowers the block B0 to a height equal to that of the upper surface of the dome 132 at the predetermined speed (s2).

### (Third Step: Step 3)

Subsequently, the control unit 80 lowers the block B1 to a height equal to that of the upper surface of the dome 132 at the predetermined speed (s2).

### (Fourth Step: Step 4)

Subsequently, the control unit 80 lowers the block B2 to a height equal to that of the upper surface of the dome 132 at the predetermined speed (s2).

### (Fifth Step: Step 5)

Subsequently, the control unit 80 lowers the block B3 to a height equal to that of the upper surface of the dome 132 at the predetermined speed (s2).

### (Sixth Step: Step 6)

Subsequently, the control unit 80 lowers the block B4 to a height equal to that of the upper surface of the dome 132 at the predetermined speed (s2).

### (Seventh Step: Step 7)

Subsequently, the control unit 80 lowers the block B5 to a height equal to that of the upper surface of the dome 132 at the predetermined speed (s2). Here, since the block B5 is lowered to the height equal to that of the upper surface of the dome 132, the dicing tape DT loses its support and due to the tension of the dicing tape DT, peeling of the dicing tape DT progresses further.

### (Eighth Step: Step 8)

Subsequently, the control unit 80 lowers the block B6 to a height equal to that of the upper surface of the dome 132 at the predetermined speed (s2). Here, since the block B6 is lowered to the height equal to that of the upper surface of the dome 132, the dicing tape DT loses its support and due to the tension of the dicing tape DT, peeling of the dicing tape DT progresses further.

### (Ninth Step: Step 9)

Subsequently, the control unit 80 lowers the block B7 to a height equal to that of the upper surface of the dome 132 at the predetermined speed (s2). Here, since the block B7 is lowered to the height equal to that of the upper surface of the dome 132, the dicing tape DT loses its support and due to the tension of the dicing tape DT, peeling of the dicing tape DT progresses further.

### (Tenth Step: Step 10)

Subsequently, the control unit 80 lowers the block B8 to a height equal to that of the upper surface of the dome 132 at the predetermined speed (s2). Here, since the block B8 is lowered to the height equal to that of the upper surface of the dome 132, the dicing tape DT loses its support and due to the tension of the dicing tape DT, peeling of the dicing tape DT progresses further.

Subsequently, the control unit 80 lifts the collet 22 upward and at the same time, lowers the block B9 at the predetermined speed (s3) and returns it to the initial position. As a result, the peeling work of the die D from the dicing tape DT is completed.

As a result, with the progress in the peeling, a peripheral peeling-starting point can be created at multiple timings.

### Thirteenth Modification Example

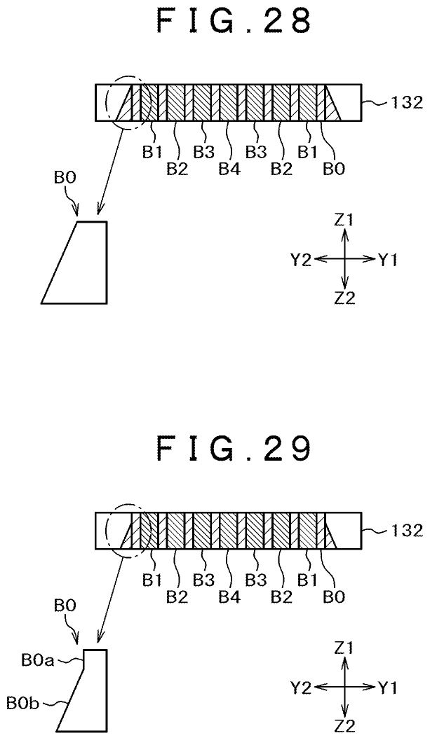

FIG. 28 is a cross-sectional view of the main portion of a push-up unit in Thirteenth Modification Example.

In the embodiment, the peripheral portion of the outside block B0 has a rectangular cross-section. In Thirteenth Modification Example, on the other hand, the peripheral portion of an outside block B0 has a trapezoidal cross-section. This making it possible to enhance the strength of the block B0.

### Fourteenth Modification Example

FIG. 29 is a cross-sectional view of the main portion of a push-up unit in Fourteenth Modification Example.

In Thirteenth Modification Example, the peripheral portion of the outside block B0 has a trapezoidal cross-section. In Fourteenth Modification Example, on the other hand, an upper portion B0a of the peripheral portion of the block B0 has a rectangular cross-section as in the embodiment and the cross-section of a lower portion B0b, which is a portion below the upper portion, is made wider as it goes lower.

The disclosure made by the present disclosing party was described specifically based on the embodiment and modification examples. It is needless to say that the present disclosure is not limited by the aforesaid embodiment and modification examples, but it can be changed in various ways.

For example, described in the embodiment was the example having seven inside blocks, however, the number of the blocks may be either smaller or larger than seven depending on a die size or the like.

In addition, described in the embodiment was the example using a die attach film, however, instead of the die attach film, a preform unit for applying an adhesive to a substrate may be provided.

Further, described in the embodiment was the die bonder for picking up a die from the wafer supply unit by means of the pick-up head, placing it on the intermediate stage, and bonding the die placed on the intermediate stage to the substrate by means of the bonding head. The device disclosed herein may be applied to not only it but also a die bonding device that picks up a die from a die supply unit.

It may also be applied to, for example, a die bonder that has neither an intermediate stage nor a pick-up head and bonds a die, which is on the wafer supply unit, to a substrate by means of a bonding head.

It may also be applied to, for example, a flip chip bonder that is not equipped with an intermediate stage and picks up a die from the wafer supply unit, delivers the die to a bonding head while turning a die pick-up head upward, and bonds it to a substrate by means of a bonding head.

In the above embodiment, the description was made with a die bonder as an example, but the invention may be applied to a semiconductor manufacturing device that places a picked-up die on a tray.

What is claimed is:

1. A semiconductor manufacturing device, comprising:
a wafer holder for holding a dicing tape to which a die is attached; and
a push-up unit having a block unit for pushing up the dicing tape, wherein
the block unit comprises:
an outside block having a first-direction length longer than a second-direction length in a planar view and having a plurality of openings; and
an inside block placed inside the openings, and
the inside blocks are plural and are placed side by side along the first direction.

2. The semiconductor manufacturing device according to claim 1, wherein
instead of the outside block, an outside block having the first-direction length longer than the second-direction length in a planar view and having one opening is provided, and
a position of the outside block to be brought into contact with the dicing tape is discontinuous or intermittent.

3. The semiconductor manufacturing device according to claim 1, wherein
instead of the outside block, a plurality of outside blocks each having one opening are provided,
the outside blocks are placed side by side along the first direction, and
the outside blocks each have therein at least one inside block that performs the same push-up operation.

4. The semiconductor manufacturing device according to claim 1, wherein
the inside blocks are circular in a planar view.

5. The semiconductor manufacturing device according to claim 1, wherein
the inside blocks have a size, in the second direction, of 0.1 mm or more and 1.5 mm or less.

6. The semiconductor manufacturing device according to claim 1, wherein
the inside blocks are polygonal or oblong in a planar view.

7. The semiconductor manufacturing device according to claim 6, wherein
the inside blocks which are polygonal in a planar view have an arc-shaped corner.

8. The semiconductor manufacturing device according to claim 1, wherein
the inside blocks have therein a plurality of members placed concentrically.

9. The semiconductor manufacturing device according to claim 1, wherein
the inside blocks are different in size in a planar view, depending on a placement position thereof.

10. The semiconductor manufacturing device according to claim 1, wherein
the peripheral surface of the outside block has a gradient with respect to a push-up center axis, and a width of the outside block on a peripheral side becomes wider as the block goes lower.

11. The semiconductor manufacturing device according to claim 1, further comprising:
a control unit for lifting or lowering the outside block and the inside blocks independently.

12. The semiconductor manufacturing device according to claim 11, wherein
the control unit is constituted to lower the inside blocks in the order of from both outside to a center.

13. The semiconductor manufacturing device according to claim 11, wherein
the control unit is constituted to lower the inside blocks in the order of from one end to the other end.

14. The semiconductor manufacturing device according to claim 11, wherein
the push-up unit further has a dome placed around the block unit, and
the control unit lifts all the inside blocks by the dome while performing adsorption of the dicing tape and then lowering the inside blocks in the order of from both outsides.

15. The semiconductor manufacturing device according to claim 11, wherein
the control unit is constituted to lift the outside block and all the inside blocks and then lift all the inside blocks while lowering the outside block.

16. A push-up unit, comprising:
a block unit that pushes up a dicing tape, wherein
the block unit comprises:
an outside block having a first-direction length longer than a second-direction length in planar view and having a plurality of openings; and
an inside block placed inside the openings, and
the inside blocks are plural and are placed side by side along the first direction.

17. A method of manufacturing a semiconductor device, comprising the steps of:
delivering, in a semiconductor manufacturing device, a wafer ring for holding the dicing tape, the semiconductor manufacturing device comprising: a wafer holder for holding a dicing tape to which a die is attached; and a push-up unit having a block unit for pushing up the dicing tape, the block unit including: an outside block having a first-direction length longer than a second-direction length in a planar view and having a plurality of openings; and an inside block placed inside the openings, the inside blocks being plural and being placed side by side along the first direction; and
peeling the die from the dicing tape.
